(19) United States
(12) Patent Application Publication
(10) Pub. No.: US 2011/0214265 A1
(43) Pub. Date: Sep. 8, 2011

(54) Piezoelectric component and manufacturing method thereof

(75) Inventor: Toshimasa Tsuda, Sayama-Shi (JP)

(73) Assignee: Nihon Dempa Kogyo Co., Ltd., Shibuya-Ku (JP)

(21) Appl. No.: 13/109,523

(22) Filed: May 17, 2011

Related U.S. Application Data
(63) Continuation of application No. 12/462,477, filed on Aug. 4, 2009.

(30) Foreign Application Priority Data
Aug. 19, 2008 (JP) JP2008-210788

(51) Int. Cl. H01L 41/22

(52) U.S. Cl. 29/25.35

(57) ABSTRACT

An object of the present invention is to; miniaturize, increase the capacity, and reduce the price of piezoelectric components. The present invention relates to a piezoelectric component and a manufacturing method thereof, characterized in that: there are bonded and laminated at least two or more piezoelectric elements in which comb-teeth electrodes, wiring electrodes having element wirings that are arranged adjacent to the comb-teeth electrodes, and electrode terminals connected to the wiring electrodes, are formed on a principal surface of a plurality of piezoelectric substrates, while forming hollow sections between the respective piezoelectric elements; through electrodes are formed in the respective piezoelectric substrates so as to pass therethrough; the through electrodes are connected to the electrode terminals; and the piezoelectric substrates are sealed by a resin sealing layer.

### CROSS-REFERENCE TO RELATED APPLICATIONS

This Application is a Continuation of application Ser. No. 12/462,477 filed on Aug. 4, 2009.

### BACKGROUND OF THE INVENTION

The present invention relates to a piezoelectric component such as a piezoelectric thin film and a surface acoustic wave (SAW) device used in a SAW duplexer and a SAW filter, to be used in mobile communication devices such as mobile phones, and a manufacturing method thereof. In particular, the invention relates to a piezoelectric component and a manufacturing method thereof in which at least two or more piezoelectric elements are flip-chip mounted on a plurality of wafers at a wafer (piezoelectric substrate) level, and these piezoelectric elements are laminated via a resin sealing layer and terminal electrodes while forming hollow sections between the piezoelectric elements, and packaged in a chip size.

For example, in a piezoelectric component (SAW device) mounted in a mobile phone, around the comb-teeth electrode sections thereof [IDT (Inter-Digital Transducer) electrode sections], there are needed predetermined hollow sections.

Conventionally, in order reduce the size of a SAW device, a SAW element chip is flip-chip bonded (face-down bonded) on an wiring substrate with use of a gold (Au) bump or solder bump, and the entirety of the SAW element chip is resin sealed with a resin or the like, to thereby configure a small size package device of the SAW device (see Japanese Unexamined Patent Publication No. 2004-147220).

Furthermore, there has been proposed a microminiaturized chip-size package SAW device in which in order to reduce the size and height of a SAW device, predetermined hollow sections are formed around comb-teeth electrode sections (IDT electrode sections), the entirety of an aggregate piezoelectric substrate (wafer) on the comb-teeth electrodes side is sealed with a resin while retaining this hollow sections, and after forming external connection electrodes, it is divided, by means of dicing, into individual SAW devices in a predetermined size (see Japanese Unexamined Patent Publication No. 2002-111218).

However, in the aforementioned piezoelectric component and the manufacturing method thereof of the conventional technique, the piezoelectric element is formed on a secondary plane (principal surface) of the piezoelectric substrate, and consequently, in order to reduce the size of the piezoelectric component (SAW device), the active surface of the piezoelectric element becomes small as a result of miniaturization thereof. Therefore, it has been extremely difficult to achieve miniaturization while maintaining the desired performance thereof.

Moreover, in a method in which piezoelectric substrates (wafers) are simply affixed and laminated on each other to thereby manufacture a piezoelectric component (see Japanese

Unexamined Patent Publication No. 2006-246112), it is necessary to form through electrodes. However, there need to be formed through holes (via holes) and there are needed a plating step for filling these through holes thereby forming the through electrodes, and a step for filling the through holes. Moreover, if materials of the piezoelectric substrates to be affixed on each other are different, there is a problem in that a warp may occur in the overall piezoelectric substrate.

The problem to be solved by the present invention is such that: there are bonded and laminated at least two or more piezoelectric elements in which comb-teeth electrodes, wiring electrodes having element wirings that are arranged adjacent to the comb-teeth electrodes, and electrode terminals connected to the wiring electrodes, are formed on a principal surface of a plurality of piezoelectric substrates, while forming hollow sections between the respective piezoelectric elements; through electrodes are formed in the respective piezoelectric substrates so as to pass therethrough; the through electrodes are connected to the electrode terminals; and the piezoelectric substrates are sealed by a resin sealing layer, thereby inexpensively manufacturing a miniaturized and highly functionalized piezoelectric component.

### SUMMARY OF THE INVENTION

In order to solve the above problems, the piezoelectric component of the present invention is characterized in that: there are bonded and laminated at least two or more piezoelectric elements in which comb-teeth electrodes, wiring electrodes having element wirings that are arranged adjacent to the comb-teeth electrodes, and electrode terminals connected to the wiring electrodes, are formed on a principal surface of a plurality of piezoelectric substrates, while forming hollow sections between the respective piezoelectric elements; through electrodes are formed in the respective piezoelectric substrates so as to pass therethrough; the through electrodes are connected to the electrode terminals; and the piezoelectric substrates are sealed by a resin sealing layer.

Moreover, similarly, the piezoelectric component manufacturing method of the present invention is characterized in that there are included steps of: preparing a piezoelectric substrate having comb-teeth electrodes and wiring electrodes formed on a principal surface thereof, and forming a protective film on the principal surface; removing, by means of photolithography and dry etching, the protective film on the surface of the comb-teeth electrodes and the wiring electrode sections thereby exposing them; forming a seed layer on the surface of the wiring electrode sections by means of photolithography; applying Cu and Sn electrolytic plating on the seed layer; laminating a cover film on an entire surface, on which the electrolytic plating has been applied; grinding a back surface of the piezoelectric substrate by a predetermined amount, and after thinning the thickness thereof, further applying sandblasting on the back surface; faulting partial through holes in the back surface of the piezoelectric substrate by means of photolithography and sandblasting; forming further complete through holes by any one of or a combination of wet etching, sandblasting, excimer laser, and dry etching; removing the photoresist remaining on the back surface of the piezoelectric substrate, and then forming a seed layer on the wiring electrodes; forming cavities for forming wiring electrodes, electrode terminals, and through electrodes, by means of photolithography, and applying electrolytic Cu plating to the cavities, thereby forming the wiring electrodes, the electrode terminals, and the through electrodes; removing the photoresist, and removing the seed layer by means of etching; laminating at least two of the piezoelectric substrates that have been processed in the respective previous steps, while the piezoelectric element formation surfaces thereof are made to face each other, and bonding them on another piezoelectric substrate that has already been patterned; sequentially affixing a heat resistant tape and a dicing film on a bottom surface of the bonded piezoelectric substrate, and then dividing only the bonded piezoelectric substrate into individual pieces by means of dicing; removing the dicing film, and then laminating and thereby resin-sealing with a resin film, the piezoelectric substrate that has been divided into individual pieces; and dividing the resin-sealed piezoelectric substrate into individual piezoelectric components by means of dicing.

It becomes possible to reduce the size of a piezoelectric component and increase the number of piezoelectric elements (high functionalization), while it is possible to batch-process them on a piezoelectric substrate (wafer) basis, thereby realizing a price reduction.

### BRIEF DESCRIPTION OF THE DRAWINGS

FIG. 1 shows a vertical sectional view of a SAW device, which is an embodiment of a piezoelectric component of the present invention.

FIG. 2 shows a step of preparing a patterned wafer [step (1)] to a step of back grinding [step (10)] in a SAW device manufacturing method, which is an embodiment of the piezoelectric component of the present invention.

FIG. 3 shows a step of sandblasting [step (11)] to a step of resist removal/seed layer etching [step (21)] in the same method.

FIG. 4 shows a step of wafer bonding [step (22)] to a step of taping [step (30)] in the same method.

### DETAILED DESCRIPTION OF PREFERRED EMBODIMENT

Hereunder, a piezoelectric component and a manufacturing method thereof of the present invention are described for an embodiment of a SAW device.

Piezoelectric Component (SAW Device)

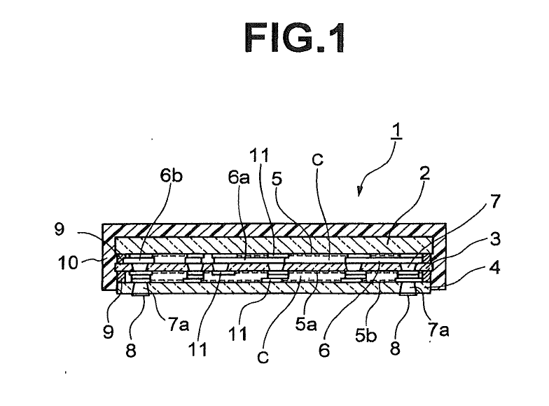

FIG. 1 shows a SAW device, which is an embodiment of a piezoelectric component of the present invention.

This SAW device 1, as shown in FIG. 1, comprises: piezoelectric substrates (wafers) 2, 3, and 4 bonded and laminated so as to form hollow sections C between a plurality, for example, three of principal surfaces having a piezoelectric function formed on a piezoelectric substrate or a substrate of lithium tantalite (LiTaO₃), lithium niobate (LiNbO₃), quartz, or the like; comb-teeth (IDT) electrodes 5, 5a, and 5b made from an aluminum film that are formed on the principal surfaces of these piezoelectric substrates 2, 2, and 4 by means of deposition or sputtering; wiring electrodes 6, 6a, and 6b that have element wirings and that connect between the comb-teeth electrodes 5, 5a, and 5b and terminal electrodes 8; inter-layer connection electrodes 11 connected to these wiring electrodes 6, 6a, and 6b; and a sealing resin 10 that seals so as to at least surrounds the outer periphery of the comb-teeth electrodes 5, 5a, and 5b. Furthermore, there are provided through electrodes 7 and 7a that pass through the piezoelectric substrates 3 and 4, other than the piezoelectric substrate 2 on the top-most layer among the piezoelectric substrates 2, 3, and 4, and that are connected to the terminal electrodes 8, and, with a sealing resin 10, the piezoelectric substrates 2, 3, and 4 having piezoelectric elements formed thereon are sealed and laminated so as to respectively form the hollow sections C between the principal surfaces thereof. Here, on the inner wall surface of the sealing resin 10, in order to prevent the sealing resin from flowing into the hollow sections C, there is provided a ring-shaped outer surrounding electrode 9. Moreover, between the piezoelectric substrates 2, 3, and 4, there are respectively provided the inter-layer connection electrodes 11.

Moreover, the SAW device 1 may be such that: there are provided a plurality of the through electrodes 7 and 7a; on the piezoelectric element active surface and on the back surface side of the piezoelectric element, there are respectively provided wiring electrodes to serve as inductor components; and with use of these inductor components, piezoelectric elements are combined as an impedance-matching circuit. With this circuit configuration, a distributed constant circuit based on a line length is formed, wirings on the upper surface and lower surface of the piezoelectric substrates are connected by through holes, and they are connected in a meander form. Thereby, it can be used as a part of the wiring length.

Furthermore, using the principal surface side of the piezoelectric substrate, the through electrodes, a rewiring layer, or an insulating layer, wirings are formed on the back surface side of the piezoelectric substrate to be further superimposed; a circuit is formed using a distributed constant (floating capacitance, wiring length), and impedance matching, phase matching; and the comb-teeth electrodes of the piezoelectric substrate are combined to thereby form a resonant circuit.

Moreover, the element wirings that configure the wiring electrodes 6 are formed from: a material whose primary component is any one of Al, Cu, Au, Cr, Ru, Ni, Ti, W, V, Ta, Mo, Ag, In, and Sn; an alloy of these materials; or wirings laminated in multiple layers.

Moreover, a plurality of element wirings are formed on the principal surfaces of the piezoelectric substrates 2, 3, and 4, and all of the element wirings are wired so as to have a same electrical potential, so that when subsequently forming the through electrodes 7 and 7a by means of electrolytic plating, the formation section for the through electrodes 7 and 7a and the element wirings can be electrically connected.

Furthermore, on the outer wall surface of the sealing resin 10 and on the surfaces of the wiring electrodes 8 and the IDT electrodes 5, there is formed a metallic layer whose primary component is gold.

Moreover, at least one piezoelectric substrate of the piezoelectric substrates 2, 3, and 4 may be formed from a base material made from one of: Si, or an organic material such as silica glass, epoxy resin, polyimide resin, cardo resin (fluorene resin), and fluorine resin.

Moreover, on a part of the surface of the piezoelectric component 1, there is laminated an active circuit made with a semiconductor element.

The piezoelectric element that forms the piezoelectric component of the present invention may, in addition to a surface acoustic wave (SAW) element, be an FBAR and an MEMS.

Piezoelectric Component Manufacturing Method

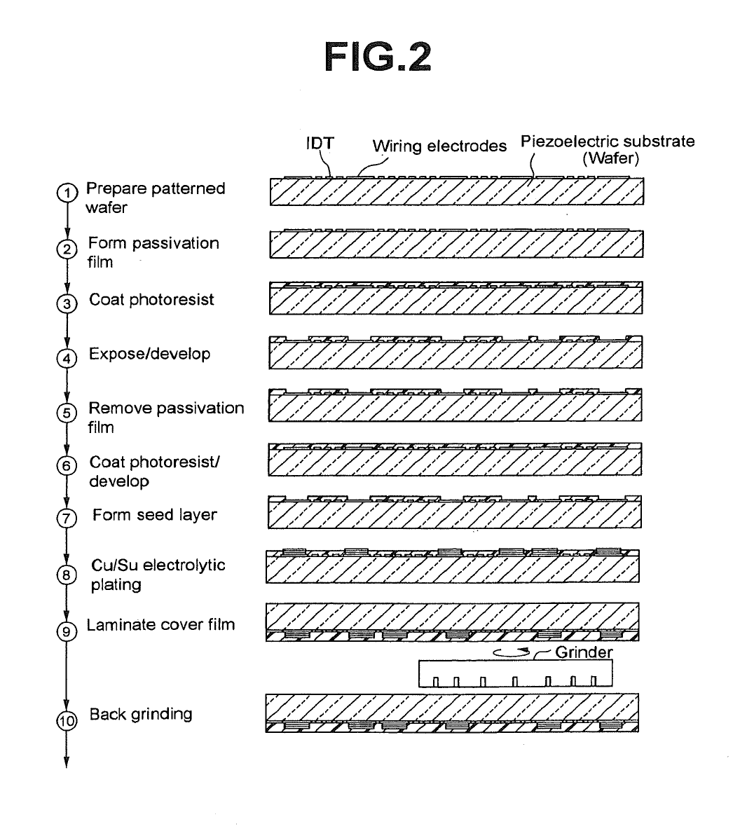

Next, there is described, with reference to FIG. 2 to FIG. 4, a piezoelectric component manufacturing method of the present invention, for a SAW device manufacturing method, which is an embodiment thereof.

First, a patterned wafer having the IDT electrodes and the wiring electrodes formed on the principal surface of the piezoelectric substrate (wafer) from Al by means of deposition or sputtering, is prepared [step (1)], and as an insulating film, a passivation film formed from SiO₂, SiN, or the like is formed on the IDT electrodes and the wiring electrodes, across the entire principal surface of the piezoelectric substrate [step (2)].

Next, a photoresist is coated on the passivation film surface [step (3)], the wiring electrode sections beneath the passivation film surface are exposed by means of exposure/development based on photolithography [step (4)], and the passivation film on the surface of the wiring electrode sections is removed by means of etching [step (5)].

Furthermore, a photoresist is coated on the entire surface of the piezoelectric substrate [step (6)], a seed layer for Cu/Cu electrolytic plating in a latter step is formed by means of exposure/development based on photolithography [step (7)], and electrolytic plating of Cu and Sn is applied on the seed layer of the upper surface of the wiring electrode sections [step (8)]. Here, in a case where the seed layer is formed from Ti/Cu or the like, Cu/Sn electrolytic plating is to be applied, and in a case where it is formed from Ti/Al, zincate processing and Ni/Sn non-electrolytic plating are to be performed. After laminating a cover film on the electrolytic-plated surface [step (9)], the back surface of the piezoelectric substrate is ground with use of a diamond grinding wheel or the like, and the thickness thereof is thinned to a predetermined thickness (for example, 150 μm) [step (10)].

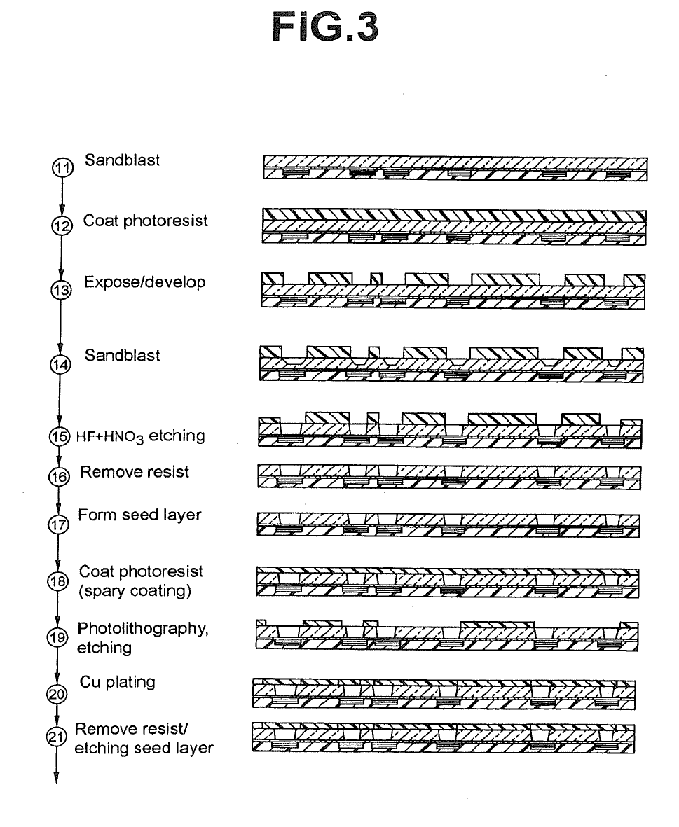

Furthermore, in the back grinding of the previous step [step (10)], since the back surface of the piezoelectric substrate has been ground with a grinder having an approximate abrasive grain size No. 2000, cutting traces due to rotation remain on the back surface of the piezoelectric substrate, and these cutting traces become a cause of cracks in the piezoelectric substrate. Consequently, in order to prevent cracks in the piezoelectric substrate, as shown in FIG. 3, sandblasting is applied on the back surface of the piezoelectric substrate, thereby forming a roughened back surface [step (11)].

Next, a photoresist is coated on the back surface of the piezoelectric substrate [step (12)], and there are partially formed, by means of exposure/development based on photolithography, holes in which the through electrodes are formed [step (13)].

Furthermore, the piezoelectric substrate is rough-cut, from the back surface thereof, along the above holes formed on the photoresist by means of sandblasting, excimer laser, or dry etching, and further complete through holes (via holes) are formed by means of wet etching with a solution of HF and HNO₃ [step (15)], and the remaining photoresist is removed from the back surface of the piezoelectric substrate [step (16)].

Next, on the wiring electrodes, there is formed, by means of plating, a seed layer for forming the through electrodes. Furthermore, a photoresist is coated on the back surface of the piezoelectric substrate by means of spray coating [step (18)], and patterning is performed by means of photolithography and there are formed cavities for forming the wiring electrodes, electrode terminals, and through electrodes [step (19)], and Cu is plated on the cavities by means of electrolytic Cu plating thereby forming the through electrodes, wiring electrodes, and electrode terminals [step (20)]. Subsequently, the resist is removed, and the seed layer is removed by means of etching [step (21)].

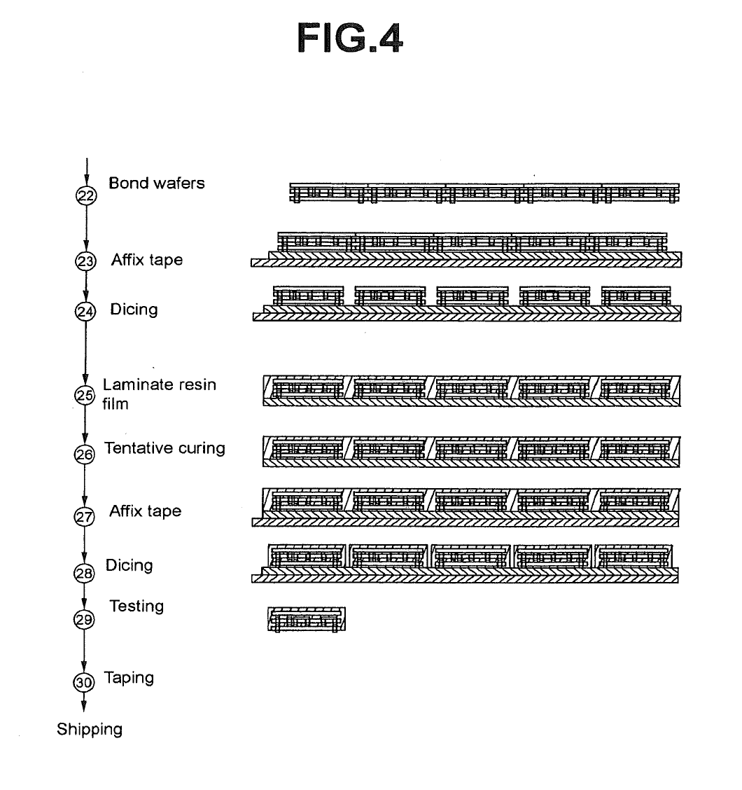

Next, as shown in FIG. 4, a plurality of the piezoelectric substrates (wafers) processed in this way are bonded while the piezoelectric element formation surfaces thereof are facing each other [step (22)], and a reinforcement heat resistant tape such as Kapton (registered trademark) tape is affixed on the bottom surface of the piezoelectric substrate and a dicing tape is further affixed on the back surface of this heat resistant tape [step (23)]. After dividing the piezoelectric substrate into individual pieces, the dicing film is removed [step (24)]. Here, each of the individual pieces (piezoelectric components) is retained by the heat resistant tape, and therefore they will not come apart.

Here, bonding of the piezoelectric substrates (wafers) is achieved by any one of: Au—Au thermocompression bonding; solid-phase diffusion bonding of Cu—Sn—Cu or Au—In metal; soldering with Au—Sn, Au—Ge, Au—Si, or Sn—Ag—Cu based solder; and cold bonding based on ion beam activation with use of Cu, Ag, or Au.

A resin film, such as insulating resin made of an organic material such as photosensitive polyimide resin and epoxy resin, is laminated on the piezoelectric substrate on a heat resistant sheet, thereby performing resin-sealing [step (25)], and after the sealing resin has tentatively cured [step (26)], where a piezoelectric substrate with piezoelectric elements laminated, for example, in two layers, can be obtained as a product of the previous steps, a dicing tape is affixed on the bottom surface of the heat resistant tape [step (27)]. Then, it is divided into individual piezoelectric components by means of dicing [step (28)].

After removing the heat resistant tape from the piezoelectric components after dicing, a characteristic test is performed [step (29)], and they are then taped [step (30)] to be shipped.

A piezoelectric component and a manufacturing method thereof of the present invention can be widely utilized for piezoelectric elements, such as a SAW device, a piezoelectric thin film filter, an FBAR, and an MEMS, and for piezoelectric components that require an extremely high level of reliability and functionality, and for a manufacturing method thereof.

1. A piezoelectric component manufacturing method comprising the steps of:
preparing a piezoelectric substrate having comb-teeth electrodes and wiring electrodes formed on a principal surface thereof, and forming a protective film on the principal surface;
removing, by means of photolithography and dry etching, said protective film on the surface of said comb-teeth electrodes and said wiring electrode sections thereby exposing them;
forming a seed layer on the surface of said wiring electrode sections by means of photolithography;
applying Cu and Sn electrolytic plating on said seed layer;
laminating a cover film on an entire surface, on which said electrolytic plating has been applied;
grinding a back surface of said piezoelectric substrate by a predetermined amount, and after thinning the thickness thereof, further applying sandblasting on the back surface;
forming partial through holes in the back surface of said piezoelectric substrate by means of photolithography and sandblasting;
forming further complete through holes by any one of or a combination of wet etching, sandblasting, excimer laser, and dry etching;
removing the photoresist remaining on the back surface of said piezoelectric substrate, and then forming a seed layer on said wiring electrodes;
forming cavities for forming wiring electrodes, electrode terminals, and through electrodes, by means of photolithography, and applying electrolytic Cu plating to the cavities, thereby forming said wiring electrodes, said electrode terminals, and said through electrodes;
removing the photoresist, and removing said seed layer by means of etching;
laminating at least two of the piezoelectric substrates that have been processed in said respective previous steps, while the piezoelectric element formation surfaces thereof are made to face each other, and bonding them on another piezoelectric substrate that has already been patterned;
sequentially affixing a heat resistant tape and a dicing film on a bottom surface of said bonded piezoelectric substrate, and then dividing only said bonded piezoelectric substrate into individual pieces by means of dicing;
removing said dicing film, and then laminating and thereby resin-sealing with a resin film, the piezoelectric substrate that has been divided into individual pieces; and dividing the resin-sealed piezoelectric substrate into individual piezoelectric components by means of dicing.

2. A piezoelectric component manufacturing method according to claim 1, wherein said through electrode is formed by any one of plating, filling with melted solder, or filling with an electrode paste.

3. A piezoelectric component manufacturing method according to claim 1, wherein bonding of said piezoelectric substrates is achieved by any one of: Au—Au thermocompression bonding; solid-phase diffusion bonding of Cu—Sn—Cu or Au—In metal; soldering with Au—Sn, Au—Ge, Au—Si, or Sn—Ag—Cu based solder; and cold bonding based on ion beam activation with use of Cu, Ag, or Au.

4. A piezoelectric component manufacturing method according to claim 1, characterized in protecting a piezoelectric element active surface of said piezoelectric substrate with a protective tape, and then thinning by grinding a back surface of said piezoelectric substrate with a diamond grinding wheel or the like.

5. A piezoelectric component manufacturing method according to claim 1, wherein grinding a back surface of said piezoelectric substrate and then roughening the back surface by sandblasting.

6. A piezoelectric component manufacturing method according to claim 1, wherein combining said piezoelectric substrate and then thinning said back surface by grinding.

7. A piezoelectric component manufacturing method according to claim 1, wherein before combining said piezoelectric substrate, thinning said back surface by grinding.

8. A piezoelectric component manufacturing method according to claim 1, wherein forming said through electrode by plating, after laminating said piezoelectric substrate.

9. A piezoelectric component manufacturing method according to claim 1, wherein using a solution of HF and HNO₃ in said wet etching.
